(19) United States
(12) Patent Application Publication
(10) Pub. No.: US 2019/0287835 A1
(43) Pub. Date: Sep. 19, 2019

(54) Interchangeable Edge Rings For Stabilizing Wafer Placement And System Using Same

(71) Applicant: YIELD ENGINEERING SYSTEMS, INC., LIVERMORE, CA (US)

(72) Inventors: WILLIAM MOFFAT, SAN JOSE, CA (US); CRAIG WALTER MCCOY, SAN JOSE, CA (US)

(21) Appl. No.: 16/263,953

(22) Filed: Jan. 31, 2019

Related U.S. Application Data
(60) Provisional application No. 62/624,811, filed on Feb. 1, 2018.

(51) Int. Cl. H01L 21/68; H01J 37/32; H01L 21/687

(52) U.S. Cl. CPC H01L 21/68; H01J 37/32724; H01J 37/32642; H01L 21/68742; H01L 21/68735; H01L 21/68707

(57) ABSTRACT

A device and method for alignment of substrates on a substrate support, such as a heated chuck. An alignment ring may be placed over the substrate support to maintain placement and alignment during processing, such as plasma processing. The aligned substrate may then be accessed by a robotic arm, as it is in a pre-determined location. Alignment rings of different interior diameters may be used for different substrate sizes. The alignment rings may be inserted onto and removed from the process oven containing the substrate support through the substrate access port, without the need to fully open the process chamber.

### CROSS-REFERENCE TO RELATED APPLICATIONS

This application claims priority to U.S. Patent Application No. 62/624,811 to McCoy et al., filed Feb. 1, 2018, which is hereby incorporated by reference in its entirety.

### FIELD OF THE INVENTION

This invention relates to substrate processing, namely a device and method for maintaining position of substrates during processing.

### BRIEF DESCRIPTION OF THE DRAWINGS

FIG. 1 is a front perspective view of a process chamber with a substrate support within according to some embodiments of the present invention.

FIG. 2 is a front view of a process chamber with a substrate support within according to some embodiments of the present invention.

FIG. 3 is a top cross-sectional view of a process chamber with a substrate support according to some embodiments of the present invention.

FIG. 3A illustrates a system for the automated insertion of wafers into a plasma chamber according to some embodiments of the present invention

FIG. 4 is a top perspective photograph of a substrate support according to some embodiments of the present invention.

FIG. 5 is a photograph of interchangeable edge rings according to some embodiments of the present invention.

FIG. 6 is a photograph of an interchangeable edge ring according to some embodiments of the present invention.

FIG. 7 is a top cross-sectional view of a process chamber with a substrate support with an interchangeable edge ring according to some embodiments of the present invention.

FIG. 8 is a top perspective photograph of a substrate support with an interchangeable edge ring according to some embodiments of the present invention.

FIG. 9 is a top cross-sectional view of a process chamber with a substrate support with an interchangeable edge ring according to some embodiments of the present invention.

FIG. 10 is a top perspective photograph of a substrate support with an interchangeable edge ring according to some embodiments of the present invention.

FIG. 11 is a top perspective of a substrate support with an interchangeable edge ring according to some embodiments of the present invention.

FIG. 12 is a top view of an edge ring according to some embodiments of the present invention.

FIG. 13 is an oblique view of an edge ring according to some embodiments of the present invention.

FIG. 14 is a partial view of a chuck with retaining blocks and an edge ring according to some embodiments of the present invention.

### SUMMARY

A device and method for alignment of substrates on a substrate support, such as a heated chuck. An alignment ring may be placed over the substrate support to maintain placement and alignment during processing, such as plasma processing. The aligned substrate may then be accessed by a robotic arm, as it is in a pre-determined location. Alignment rings of different interior diameters may be used for different substrate sizes. The alignment rings may be inserted onto and removed from the process oven containing the substrate support through the substrate access port, without the need to fully open the process chamber.

### DETAILED DESCRIPTION

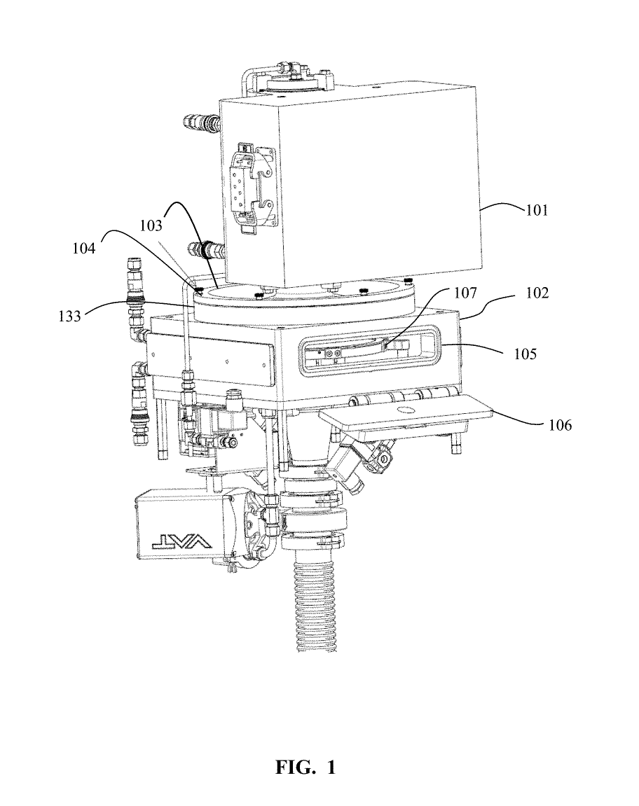

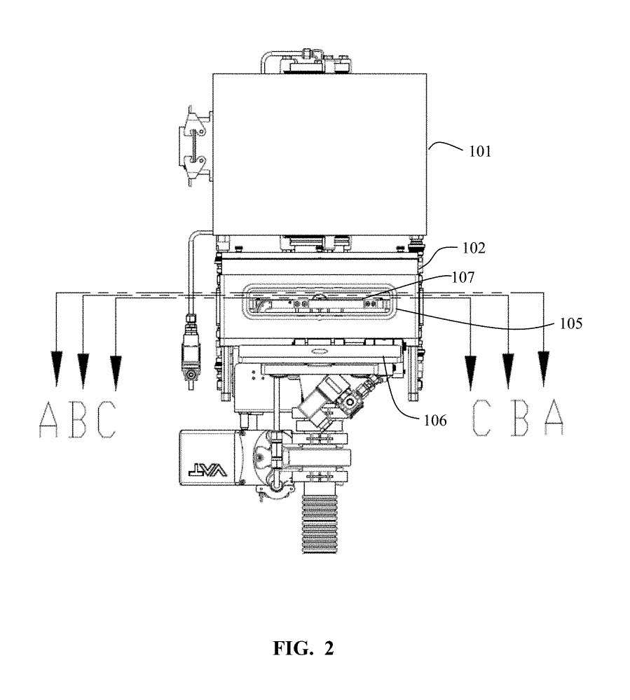

In some embodiments of the present invention, as seen in FIGS. 1-2, a plasma processing system is comprised of plasma source 101 mounted above a lower process chamber 102. The chamber 102 may be opened by removing a chamber top. A plasma source 101 may be mounted onto the chamber top. The plasma source 101 may be fastened to the chamber top 103 by fasteners 104. A heated chuck 107 may reside within the chamber 102. Installation and removal of the heated chuck is done through the top of the chamber 102 after removal of the chamber top 103. An access door 106 allows access into the chamber 102 through an access port 105. The access port 106 is adapted to allow for the insertion of substrates, such as silicon wafers, into the chamber 102 for processing. The opening of the access door 106 to allow entry into the chamber 102 through the access port 105 is a significantly easier operation than gaining access to the chamber by removing the chamber top 103. Removal of the chamber top 103 may take a significant amount of time.

As seen in FIG. 2, the access port 105 presents a significantly smaller opening into the process chamber inner area than would be presented with the removal of the chamber top. The chamber top may be removed to allow for installation of the chuck, for example, and for other tasks needing significant area of access. The access port 105 is used for the insertion and removal of wafers to support processes within the process chamber. In embodiments of the present invention, the access port may be used to insert and remove edge rings. With the use of the access port, an edge ring may be installed without the significant amount of work and of down time that would be required to access the process chamber inner area by removing the chamber top. Further, the use of easily insertable and removable edge rings, which may be inserted and removed using the access port otherwise used for wafer insertion, allows for alteration of the process chamber to allow for processing different size wafers with relative ease. In this exemplary embodiment, the process chamber 102 is adapted to process a single wafer at a time, while the wafer lays horizontally on a chuck 107.

A plurality of edge rings may be used with a chamber. A different edge ring may be used for different size wafers. As discussed below, a kit, or set, of edge rings may be used to allow for fitting of the chuck within the chamber with an edge ring of appropriate size for the wafer desired to be processed. For example, the same chuck set up in the inner area of a process chamber may be used with different edge rings adapted to align different size wafers, such as 2 inch, 4 inch, 6 inch, and 8 inch wafers. The edge rings may be adapted to be centered and aligned to the chuck similarly, and may have the same outside diameter. They may include alignment pins for alignment to the chuck, or the chuck may have retention blocks for retaining and aligning the edge rings to the chuck. When an operator desires to process wafers of a certain size, and to use an edge ring to maintain position of the wafers on the chuck, an edge ring of the appropriate inner diameter size for selected wafer size may be inserted via the access door, without requiring the more complex process of removing the chamber top. Then, should a different size wafer subsequently be desired to be processes, the first edge ring may be removed via the access door, and the subsequent edge ring may be inserted via the access door.

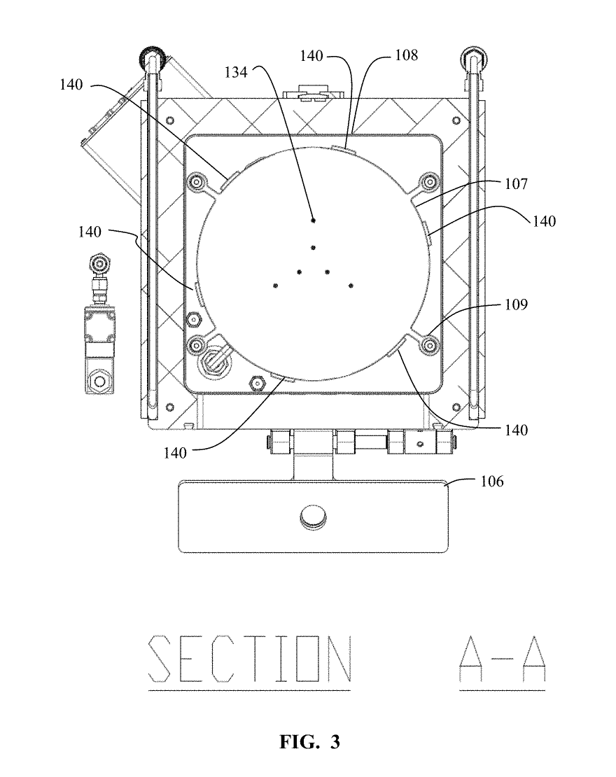

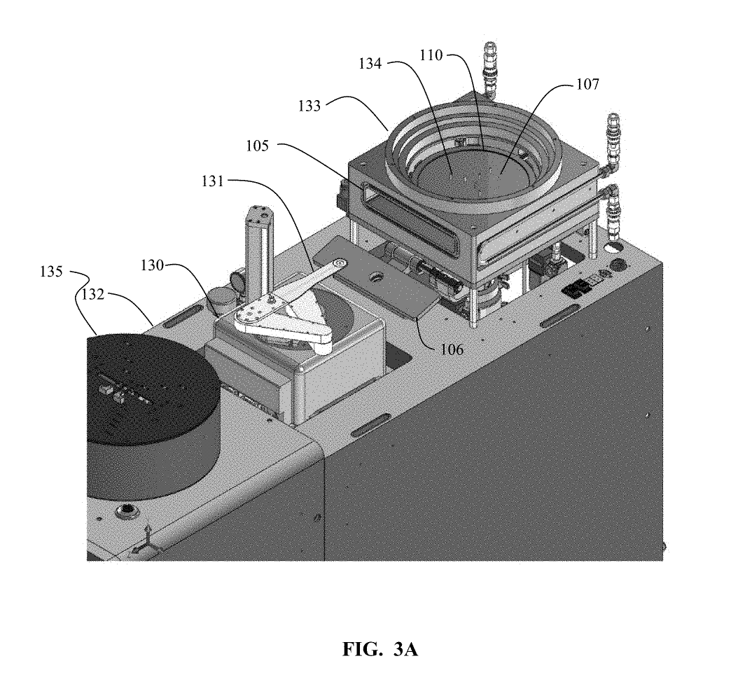

FIG. 3 illustrates a top view within the chamber 102. The chuck 107, which may be a heated chuck, may be installed into the chamber and attached via mounting points 109. The interior 108 of the chamber 102 may be, and typically will be, of larger dimension than that of the access port 105. Installation and removal of the chuck 107 may require significant disassembly of the chamber 102, which may be more than removal of the plasma source 101 and the chamber top 103. In some embodiments of the present invention, retaining blocks 140 are in place around the periphery of the top surface of the chuck 107. The retaining blocks 140 are adapted to positionally retain an edge ring, as discussed further below.

Lift pins 134 may be part of the chuck 107 and may allow for lifting of a wafer above the top surface of the chuck 107. During insertion of a wafer through the access port 105 the lift pins may already be raised, allowing for the placement of an inserted wafer on top of lifted pins. The raised wafer may allow for an arm of a robot to be under the wafer for insertion, allowing then for the removal of the arm, and then the lowering of the wafer onto the top surface of the chuck. Although the outer profile of the chuck 107 is seen as circular, in some aspects other profiles may be used.

FIG. 3A illustrates a system 131 for the automated insertion of wafers into a plasma chamber according to some embodiments of the present invention, shown in a state of partial disassembly for clarity. A cassette of wafers may reside on a cassette platform 135. In a typical example, a cassette of 25 wafers may be stacked vertically within a cassette adapted to hold and transport the wafers. A robot 130 is adapted to transport a wafer from a slot in the cassette into the chamber via the access port 105, while the access door 106 is open. A transport arm 131 is adapted to move a wafer in three dimensions, and may have a vacuum suction tip which holds the wafer firmly onto the transport arm 131. In a typical example, the transport arm 131 is moved by the robot 130 under a wafer in the cassette and then the wafer is sucked onto the transport arm with the vacuum suction tip, providing holding force to hold the wafer on the transport arm. The wafer is then carefully withdrawn from the cassette and transported through the access port 105 and centered over the chuck 107 above the raised lift pins 134. The wafer is placed onto the raised lift pins 134, the holding force holding the wafer to the transport arm is released, and then the transport arm 131 is withdrawn. The lift pins 134 are lowered and the wafer then resides on the top surface of the chuck 107.

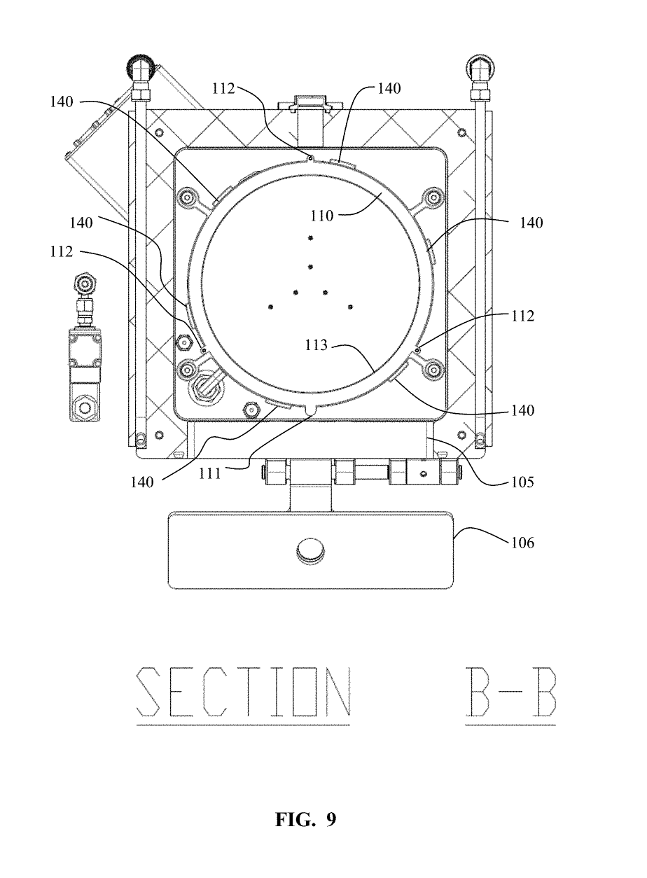

FIG. 9 illustrates a top cutaway view of a process chamber of a system 131 for the automated insertion of wafers into a plasma chamber according to some embodiments of the present invention with an edge ring 110. The edge ring 110 is adapted to provide a raised surface around the edge of a wafer in order to provide positional retention of the wafer. The edge ring may have a circular inner profile adapted for a circular wafer. The edge ring is adapted to be inserted through the access port 105. The largest dimension of the edge ring is smaller than the dimension across the access port, allowing the edge ring to be inserted through the access port. The edge ring may be inserted into the access port as long as it can fit in through the access port. In some aspects, the outer diameter of a circular edge ring will be smaller than the horizontal dimension of the opening of the access port. In some aspects, the outer diameter of a circular edge ring will be smaller than an angular dimension across the access port, such as from the lower left corner across to the upper right corner. Although illustrated with a circular outer diameter and a circular inner diameter, other exterior and interior profiles may be used.

In some embodiments of the present invention, alignment pins 112 may be used to align the edge ring 110 itself onto the chuck. An insertion tab 111 may be used to allow for insertion of the edge ring into a process chamber through an access port, using extended reach pliers, for example. The location of the alignment pins 112 on the alignment ring 110 allows for a snug fit of the alignment ring 110 onto the chuck 107, centering the inner profile of the edge ring on the chuck. In some aspects, the alignment pins may reside along an outer surface of the chuck when the edge ring is on the chuck. In some aspects, the alignment pins may mate into holes in the chuck or other components.

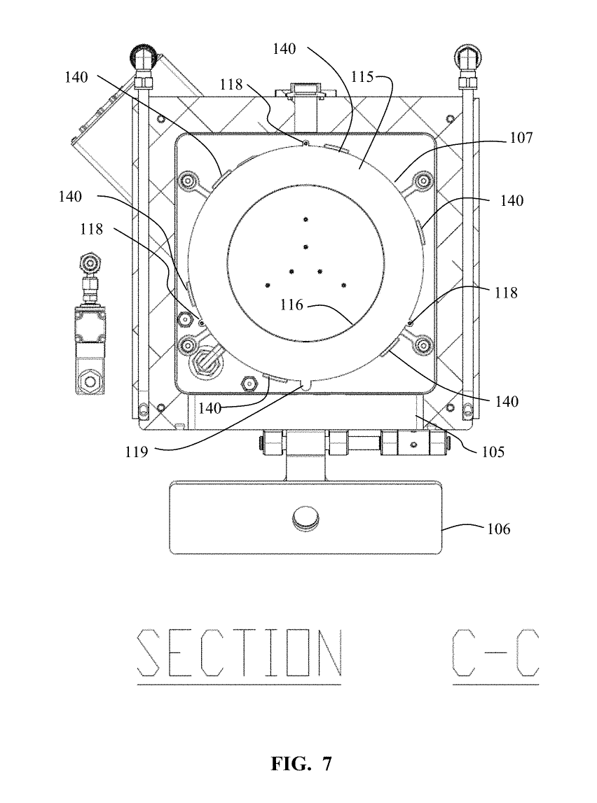

In some embodiments of the present invention, a plurality of retaining blocks 140 are in place around the periphery of the chuck 107. The retaining blocks form a retaining barrier around the outer periphery of the edge ring, providing alignment to retain the edge ring in place. In some aspects, there is a plurality of retaining blocks 140. In some aspects, the retaining barrier may be formed of a continuous barrier. Although the illustrative embodiments of FIGS. 7 and 9 utilize both retaining blocks 140 to align the edge ring and also alignment pins 112, 118 to align the edge ring, in some embodiments the edge rings may be positionally aligned and retained with just the alignment pins, or with just the retaining blocks.

The wafer is placed in a centered position on the chuck and, when lowered, resides just within the inner periphery of an edge ring 110. The edge ring 110 may function as an alignment device so that the wafer remains in the same centered position during and after processing in the process chamber 102. The access door 106 may be closed and a process may begin.

In an exemplary process, the wafer is 200 mm in diameter and 0.025 inches thick. An edge ring is placed onto the chuck via the access door. The edge ring may have an interior diameter which is 2 mm larger than the outside diameter of the wafer or wafers to be processed. In some aspects, the edge ring may have an interior diameter which is in the range of 1-3 mm larger than the outside diameter of the wafer. In some aspects, the ID of the edge ring may be in the range of 1-5 m larger than the OD of the wafer. The wafer is then inserted into process chamber via the access door. The wafer may be inserted using a robotic arm which first removes the wafer from an adjacent cassette of wafers, and then transports the wafer through the access port and centers it onto lift pins raised from the chuck top surface. The robotic arm may then be removed from the inner area of the process chamber. The wafer is lowered onto the chuck, where it resides on the chuck and within the confines of the inner diameter of the edge ring, which provides is positional alignment and stability. The access door may then be closed in order to seal the access. Port. The wafer may then be heated using the heated chuck, and vacuum may be pulled to approximately 1 Torr to support plasma processing. After the plasma processing is complete, the chamber is returned to regular atmospheric pressure, either with an inflow of air, or nitrogen, or other gas. Without an edge ring, the inrush of air or other gas may cause the wafer to move on the chuck. Should the wafer have moved far enough, the wafer may be damaged upon removal from the chamber, or during transport, or upon reinsertion into the cassette as the wafer not being centered on the transport arm may result in the extending edge of the non-centered wafer to impact a surface, such as the cassette holder. With an edge ring, the wafer is maintained in a position that is centered enough that this risk of being non-centered is either substantially reduced or eliminated entirely. After the chamber is returned to atmospheric pressure, the access door is opened, allowing the robotic arm to remove the wafer. The wafer is lifted on the lift pins and the robotic arm moves underneath it. The wafer is centered on the robotic arm as is has had its position maintained during processing and during the return to regular atmospheric pressure. The maintenance of position of the wafer by the edge ring, as described above may then lead to reduced damage to wafers during processing, increasing process efficiency and lowering cost.

As seen in the preceding Figures, a chuck is a large item and typically cannot be installed via the access port 105. Should the user desire to use the process chamber to process more than one size of wafer a permanent edge ring of a fixed interior dimension will not suffice. A removable edge ring, which may be installed via the access port 105, will allow for the changing out of one edge ring for another, thereby changing the interior dimension of the edge ring on the chuck without the extremely time consuming task of opening the chamber. A set, or kit, of edge rings of differing inner diameters but adapted to mate to the same chuck allows for much easier modification of the process chamber when the operator desires to change the size of the wafer(s) to be processed.

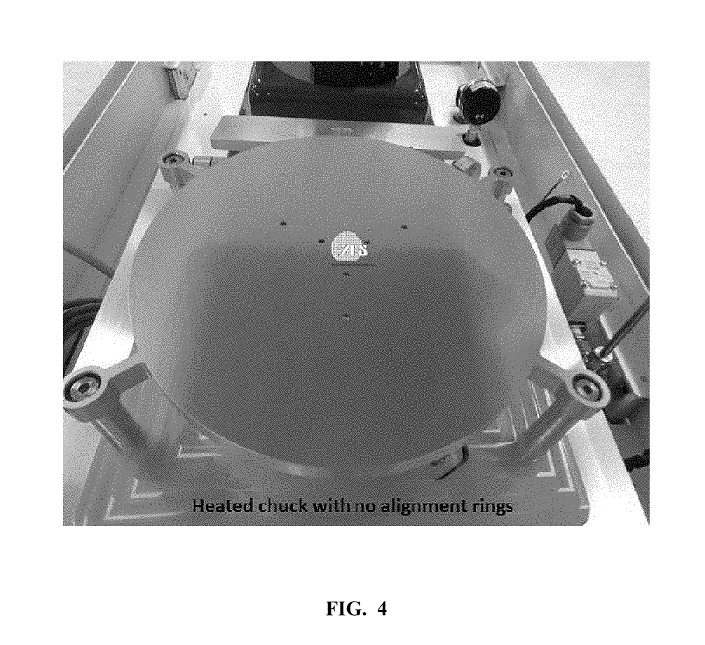

FIG. 4 is a photograph of a heated chuck without alignment rings. As seen, the heated chuck may be mounted using features which present a dimension too large to enter through an access port. Further, the attachment of the chuck may not be feasible or practical through the limited access through the access port.

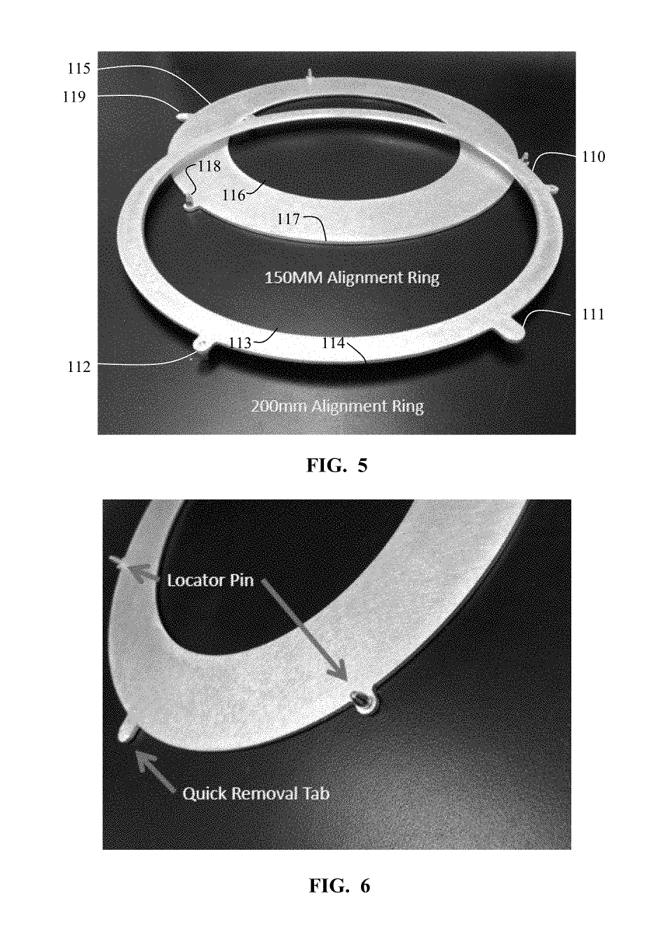

FIGS. 5 and 6 are photographs of alignment rings, or edge rings, according to some embodiments of the present invention. A first alignment ring 110 has an interior dimension 113 for use with a wafer of a first outside diameter of 200 mm. The outside diameter 114 of the alignment ring 110 may depend upon the geometry of the chuck to which it will mate, and may be approximately 9 inches, for example. Alignment pins 112 may be used to align the alignment ring 110 itself onto the chuck. An insertion tab 111 may be used to allow for insertion of the alignment ring into a process chamber through an access port, using extended reach pliers, for example. The alignment pins 112 are adapted to fit over the outside of the chuck top surface. In some aspects, the alignment pins may fit into holes in the chuck top surface. In some aspects, the alignment pins may interface with separate interface portions. In some aspects, the edge ring is adapted to be positionally retained on the chuck using retaining blocks only, and may not have alignment pins on the edge ring.

A second alignment ring 115 has an interior dimension 116 for use with a wafer of a second outside diameter of 150 mm. The outside diameter 117 of the alignment ring 115 may depend upon the geometry of the chuck to which it will mate. Alignment pins 118 may be used to align the alignment ring 110 itself onto the chuck. An insertion tab 119 may be used to allow for insertion of the alignment ring into a process chamber through an access port. In some aspects, the edge ring is adapted to be positionally retained on the chuck using retaining blocks only, and may not have alignment pins on the edge ring.

FIG. 7 illustrates a chuck 107 in a process chamber with an alignment ring 115 mounted thereon. The edge ring 115 is sized so that it may be inserted through the access port 105 when the access door 106 is opened. The edge ring may be handled by the tab 119. The edge ring is easily inserted through the access door and onto the top surface of the chuck 107. Similarly, the edge ring 115 may also be easily removed through the access port 105.

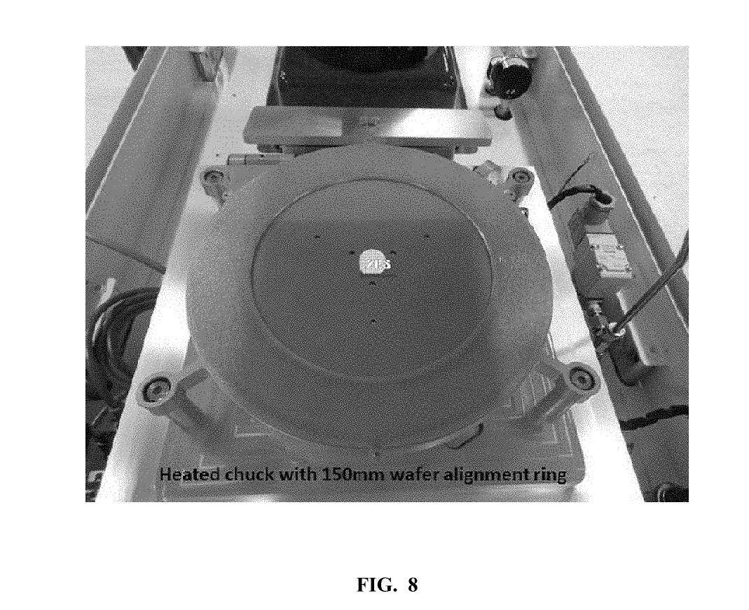

FIG. 8 is a photograph of a chuck with an alignment ring 115 mounted thereon. In this illustrative photograph, the chuck is not seen in a process chamber. The inner diameter of the edge ring presents positional alignment of a wafer which may be placed onto the chuck and just within the interior diameter of the edge ring. The chuck is too large to be inserted through the access port.

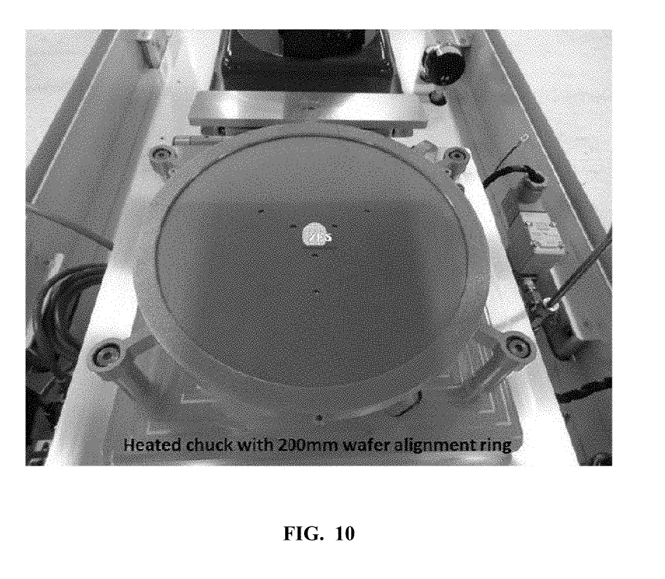

FIG. 10 is a photograph of a chuck with an alignment ring 110 mounted thereon. In contrast to the alignment ring seen in FIG. 8, the alignment ring as seen in FIG. 10 has a much larger inner diameter, and is adapted for a larger wafer. With the easily insertable and removable edge rings as seen herein, a process chamber may be easily adapted to process wafers of different sizes, with different diameters. The interchangeable edge rings allow for positional maintenance of the wafer during processing which might otherwise be moved during processing, which can lead to problems, as discussed above. Thus, the edge rings can be changed, allowing for proper processing of different size chambers, without opening and disassembly of the chamber (other than the opening of the access door).

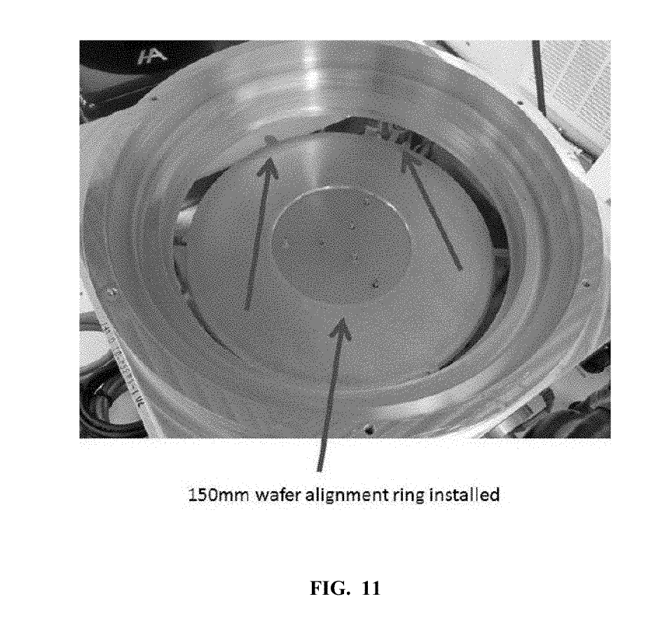

FIG. 11 is a photograph of an alignment ring on a chuck. In this illustrative example, an edge ring with an even smaller inner diameter than seen in FIGS. 8 and 10 resides on the top surface of the chuck. FIG. 11 illustrates an edge ring with a 4 inch inner diameter.

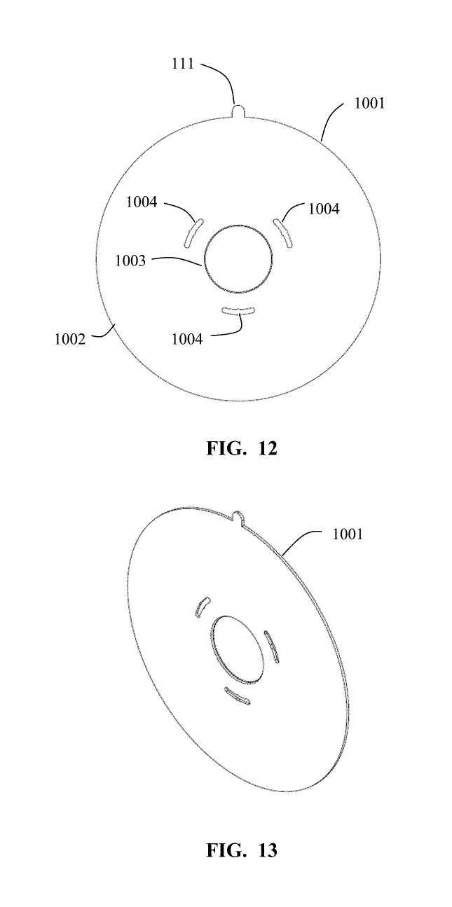

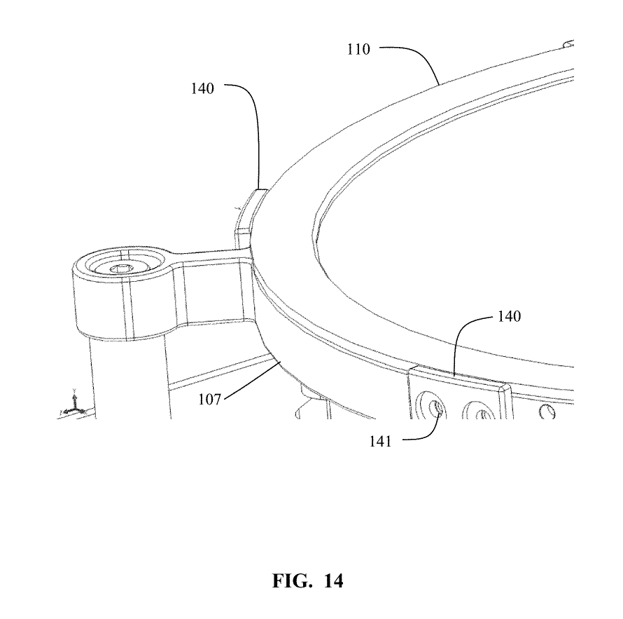

FIG. 12 illustrates an edge ring 1001 according to some embodiments of the present invention. The edge ring 1001 has an outer diameter 1002 adapted to fit within the retaining blocks of a chuck. The inner diameter 1003 of the edge ring 1001 is adapted to positionally retain a 2 inch wafer. In this embodiment, the inner diameter 1003 of the edge ring 1001 is small enough that some of the lift pins 134 are radially further out than the inner diameter of the edge ring. Slots 104 allow for the raising of the lift pins which would have otherwise been underneath the edge ring material. In some aspects, the slots are radial slots which a slightly smaller in width than the diameter of the lift pins, with a larger dimension aspect at the middle of the slot length, such that the raised pins can be easily guided into the slots, and then the slots can be centered such that the edge ring is lowered to the top surface of the chuck. The larger dimension aspect at the middle of the slot length allows for the lift pins to fit through the slot at these points.

FIG. 13 illustrates in partial view a chuck 107 with retaining blocks 140 positionally retaining an edge ring 110. The edge ring 110 has an outer diameter which is positioned and centered by a plurality of retaining blocks 140. The retaining blocks 140 may be attached to the outside perimeter of the chuck 107 using fasteners 141.

As evident from the above description, a wide variety of embodiments may be configured from the description given herein and additional advantages and modifications will readily occur to those skilled in the art. The invention in its broader aspects is, therefore, not limited to the specific details and illustrative examples shown and described. Accordingly, departures from such details may be made without departing from the spirit or scope of the applicant's general invention.

What is claimed is:

1. A plasma process chamber system, said plasma process chamber system comprising:
a process chamber;
a plasma source coupled to said process chamber;
chuck adapted to support a wafer during processing, said chuck residing within said process chamber;
an access port, said access port located on a front side of said process chamber, said access port adapted to allow for insertion of a wafer into the process chamber and onto the chuck;
an access door, said access door coupled to said process chamber, said access door adapted to seal said access port when closed; and
a first removable alignment ring, said removable alignment ring adapted to center a wafer on said chuck, said first removable alignment ring insertable into and removable from said process chamber through said access port, said first removable alignment ring comprising an outer periphery of a first outer diameter, and a central hole of a first inner diameter.

2. The process chamber system of claim 1 further comprising a plurality of retention blocks attached around the periphery of said chuck, said plurality of retention blocks protruding above a top surface of said chuck, said plurality of retention blocks positioned to retain an alignment ring of said first outer diameter when said first removable alignment ring is placed on the top surface of said chuck.

3. The process chamber system of claim 1 wherein said first removable alignment ring further comprises a plurality of alignment pins, said alignment pins attached to the outer periphery of said first removable alignment ring, wherein said alignment pins reside along the outer periphery of said chuck when said first removable alignment ring is placed on the top surface of said chuck.

4. The process chamber system of claim 2 further comprising a robot, said robot adjacent to said process chamber, said robot adapted to insert wafers onto said chuck through said access port.

5. The process chamber system of claim 3 further comprising a robot, said robot adjacent to said process chamber, said robot adapted to insert wafers onto said chuck through said access port.

6. The process chamber system of claim 1 further comprising a second removable alignment ring, said second removable alignment ring adapted to center a wafer on said chuck, said alignment ring insertable into and removable from said process chamber through said access port, said second removable alignment ring comprising an outer periphery of a first outer diameter, and a central hole of a second inner diameter, said second inner diameter larger than said first inner diameter.

7. The process chamber system of claim 2 further comprising a second removable alignment ring, said second removable alignment ring adapted to center a wafer on said chuck, said alignment ring insertable into and removable from said process chamber through said access port, said second removable alignment ring comprising an outer periphery of a first outer diameter, and a central hole of a second inner diameter, said second inner diameter larger than said first inner diameter.

8. The process chamber system of claim 4 further comprising a second removable alignment ring, said second removable alignment ring adapted to center a wafer on said chuck, said alignment ring insertable into and removable from said process chamber through said access port, said second removable alignment ring comprising an outer periphery of a first outer diameter, and a central hole of a second inner diameter, said second inner diameter larger than said first inner diameter.

9. The process chamber system of claim 6 further comprising a third removable alignment ring, said third removable alignment ring adapted to center a wafer on said chuck, said alignment ring insertable into and removable from said process chamber through said access port, said third removable alignment ring comprising an outer periphery of a first outer diameter, and a central hole of a third inner diameter, said third inner diameter larger than said second inner diameter.

10. The process chamber system of claim 7 further comprising a second removable alignment ring, said second removable alignment ring adapted to center a wafer on said chuck, said alignment ring insertable into and removable from said process chamber through said access port, said second removable alignment ring comprising an outer periphery of a first outer diameter, and a central hole of a second inner diameter, said second inner diameter larger than said first inner diameter.

11. The process chamber system of claim 8 further comprising a second removable alignment ring, said second removable alignment ring adapted to center a wafer on said chuck, said alignment ring insertable into and removable from said process chamber through said access port, said second removable alignment ring comprising an outer periphery of a first outer diameter, and a central hole of a second inner diameter, said second inner diameter larger than said first inner diameter.

12. A method for the processing of substrates, said method comprising the steps of:
inserting a first edge ring through the access port of a process chamber and onto the top surface of a chuck with said process chamber, said edge ring comprising an annulus of a first diameter;
inserting a wafer through the access door of said process chamber onto lift pins extending from said top surface of said chuck; and
lowering said wafer into said annulus of said edge ring.

13. The method of claim 12 further comprising the step of closing an access door coupled to said process chamber to seal said access port.

14. The method of claim 13 further comprising the step of reducing pressure in said process chamber after the step of closing the access door coupled to said process chamber to seal said access port.

15. The method of claim 14 further comprising the step of plasma processing said wafer.

16. The method of claim 15 further comprising the steps of:
opening said access door to allow access to said process chamber through said access port; and
removing said wafer through said access port.

17. The method of claim 16 further comprising the steps of:
removing said first edge ring; and
inserting a second edge ring, said second edge ring comprising an annulus of a second diameter.

18. The method of claim 12 further comprising the steps of:
removing said first edge ring; and
inserting a second edge ring, said second edge ring comprising an annulus of a second diameter.

19. The method of claim 18 further comprising the steps of:
removing said second edge ring; and
inserting a third edge ring, said third edge ring comprising an annulus of a third diameter.
